(19) United States
(12) Patent Application Publication
(10) Pub. No.: US 2012/0120626 A1
(43) Pub. Date: May 17, 2012

(54) FIXING APPARATUS FOR PORTABLE DEVICE

(75) Inventor: Fumitoshi AKAIKE, Miyoshi-shi (JP)

(73) Assignee: TOYOTA BOSHOKU KABUSHIKI KAISHA, Aichi-ken (JP)

(21) Appl. No.: 13/295,430

(22) Filed: Nov. 14, 2011

(30) Foreign Application Priority Data
Nov. 16, 2010 (JP) 2010-255544

(51) Int. Cl. H05K 7/02

(52) U.S. Cl. 361/807

(57) ABSTRACT

A fixing apparatus for a portable device mounted to a vehicle seat is provided. The fixing apparatus includes a first fixing part that is supported rotatably by a first support part attached to the vehicle seat, and a second fixing part that is supported rotatably by a second support part attached to the vehicle seat. At least one of the first and second fixing parts is configured to be slidable in a direction of getting close to and away from the other of the fixing parts, and the portable device is sandwiched and fixed between the first and second fixing parts.

### BACKGROUND OF THE INVENTION

1. Field of the Invention

The present invention relates to a fixing apparatus for a portable device, which is used to fix a portable device to a vehicle seat.

2. Description of the Related Art

For example, JP-A-Hei.3-128007 describes an apparatus that fixes a portable device, such as a small television receiver, in a vehicle. An apparatus (shown in FIGS. 3 and 4 of JP-A-Hei.3-128007), which is described as the conventional embodiment in JP-A-Hei.3-128007, attaches a box-shaped case to a vehicle seat by using an attaching pole of a headrest and accommodates a portable device in the case. In addition, an apparatus (shown in FIGS. 1 and 2 of JP-A-Hei.3-128007), which is described as an inventive embodiment in JP-A-Hei.3-128007, has a configuration of fixing the portable device to a mount pole of the headrest and allowing vertically movement of the portable device together with the headrest. When moving the headrest in a downward direction, the portable device is accommodated in a recessed part formed at an upper end of a seatback.

According to the configuration described as the conventional embodiment in JP-A-Hei.3-128007, the portable device is accommodated in the box-shape case. Therefore, this configuration cannot cope with a variety of devices. In other words, only when attaching a case corresponding to a size of a portable device being used, the portable device can be stably fixed. In addition, the apparatus described as the inventive embodiment in JP-A-Hei.3-128007 has such a configuration that the portable device can be used only when vertically moving the headrest. Therefore, the usability is not high.

### SUMMARY OF THE INVENTION

The present invention has been made in view of the above circumstances, and an object of the present invention is to provide a fixing apparatus for a portable device having high usability and capable of stably fixing portable devices having various sizes.

According to an illustrative embodiment of the present invention, there is provided a fixing apparatus for a portable device mounted to a vehicle seat. The fixing apparatus comprises: a first fixing part that is supported rotatably by a first support part attached to the vehicle seat; and a second fixing part that is supported rotatably by a second support part attached to the vehicle seat. At least one of the first and second fixing parts is configured to be slidable in a direction of getting close to and away from the other of the fixing parts, and the portable device is sandwiched and fixed between the first and second fixing parts.

According to the above configuration, it is possible to freely set the interval between the first and second fixing parts sandwiching the portable device therebetween, and therefore, a variety of portable devices having different sizes can be stably fixed.

### BRIEF DESCRIPTION OF THE DRAWINGS

The above and other aspects of the present invention will become more apparent and more readily appreciated from the following description of illustrative embodiments of the present invention taken in conjunction with the attached drawings, in which:

FIG. 1 is a view showing an outer appearance of a fixing apparatus for a portable device according to an illustrative embodiment of the present invention in a state where fixing parts are closed;

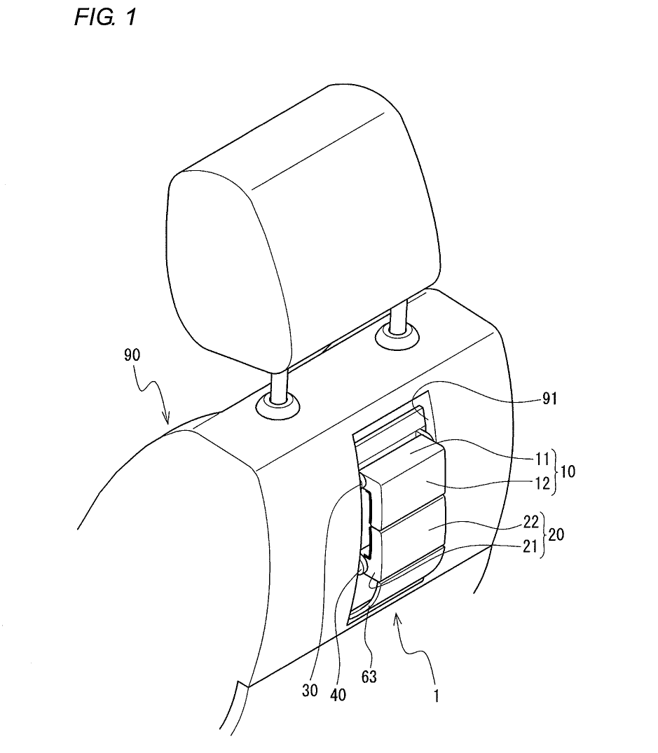

FIG. 2 is a view showing an outer appearance of the fixing apparatus according to the illustrative embodiment in a state where the fixing parts are opened;

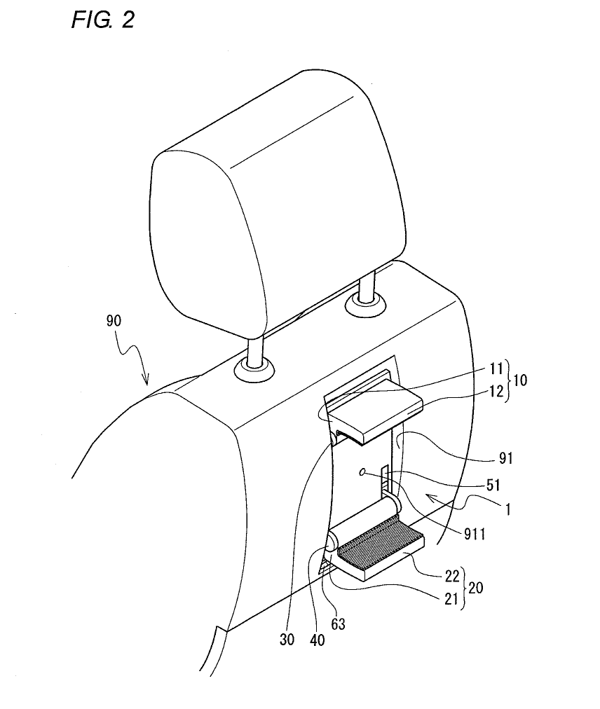

FIG. 3 is a view showing an outer appearance of the fixing apparatus according to the illustrative embodiment in a state where a portable device is fixed;

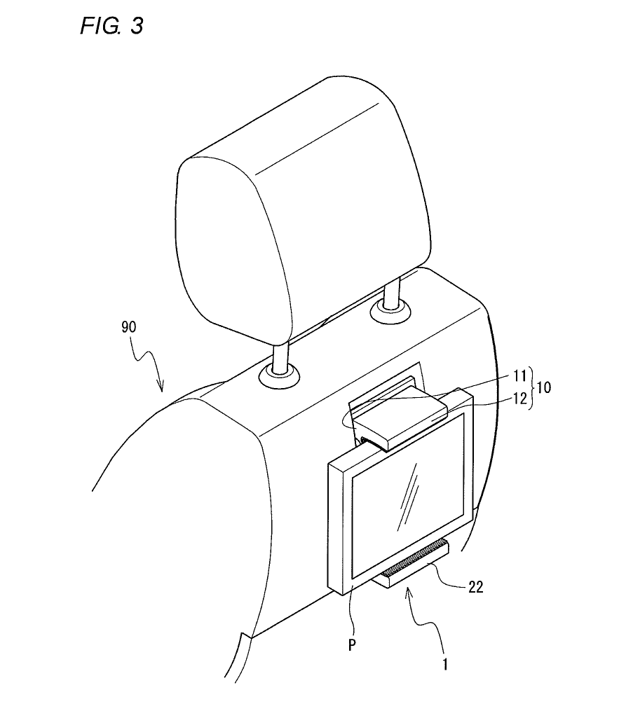

FIG. 4 is a view (hatching omitted) schematically showing a section of the fixing apparatus according to the illustrative embodiment in the state where the fixing parts are closed;

FIG. 5 is a view (hatching omitted) schematically showing a section of the fixing apparatus according to the illustrative embodiment in the state where the portable device is fixed;

FIG. 6 is a view (hatching omitted) schematically showing a section of the fixing apparatus according to the illustrative embodiment, wherein an angle of the portable device is adjusted by using an angle holding mechanism (the adjusted angle is different from that of FIG. 5);

FIG. 7 is a schematic view showing an internal configuration of the angle holding mechanism when a first fixing part is closed;

FIG. 8 is a schematic view showing the internal configuration of the angle holding mechanism when the first fixing part is opened; and

FIG. 9 is a schematic view showing the internal configuration of the angle holding mechanism when the first fixing part is rotated from an opened state to a slightly closed state.

### DETAILED DESCRIPTION

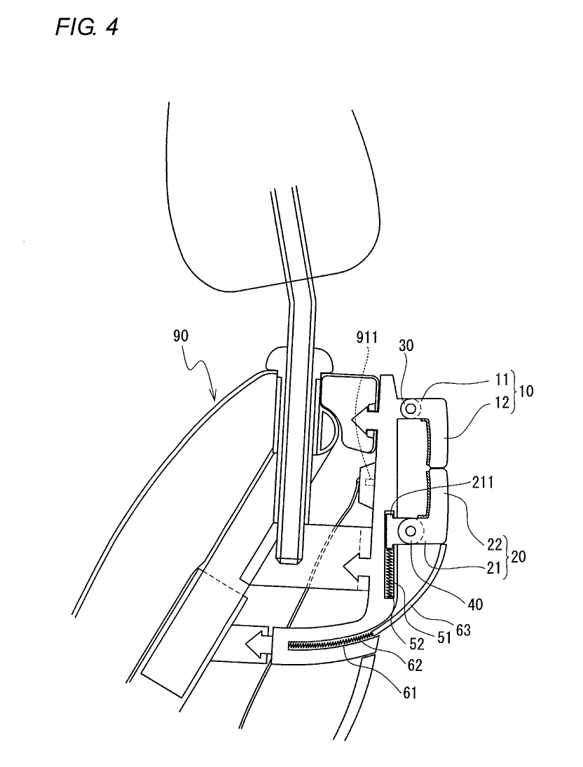

Hereinafter, illustrative embodiments of the present invention will be specifically described with reference to the drawings. In the following descriptions, a vertical direction (height direction) indicates a height direction of a vehicle seat and is a vertical direction in FIGS. 4 to 6. A front direction indicates a seating surface side of a vehicle seat and is a left direction in FIGS. 4 to 6, and a rear (backside) direction indicates an opposite direction thereto and is a right direction in FIGS. 4 to 6. A width direction is a width direction of the vehicle seat and indicates a direction that is orthogonal to the vertical direction and the left-right direction.

A fixing apparatus 1 according to an illustrative embodiment is an apparatus for fixing a portable device P such as a small television receiver, a car navigation and the like to a vehicle seat and is mounted to an upper part of a seatback 90 of the vehicle seat. The fixing apparatus 1 has first fixing part 10 that is rotatably supported by a first support part 30 and a second fixing part 20 that is rotatably supported by a second support part 40.

The first fixing part 10 is a member that has a substantially L-shaped section and a constant length in a width direction. The first fixing part 10 has a base end portion 11 and a holding portion 12 that is substantially orthogonal to the base end portion 11 when seen from a section. The first fixing part 10 is rotatably supported at the upper end of the seatback 90 by the first support part 30. The detailed configuration is explained next. A recessed part 91 that has an opened upper side and a predetermined size is formed on a backside of the seatback 90. The first support part 30 is provided to both sides of an upper end the recessed part 91. The first support part 30 connects both sides of the upper end of the recessed part 91 and the base end portion 11 of the first fixing part 10 and supports the first fixing part 10 so that the first fixing part can be rotated in an upward direction. Specifically, the first support part 30 supports the first fixing part so that the first fixing part can be rotated from a state where the backside of the seatback 90 and the holding portion 12 of the first fixing part 10 are substantially parallel (hereinafter, the state is also referred to as a closed state) to a state where an angle between the backside of the seatback 90 and the holding portion 12 of the first fixing part 10 becomes a predetermined angle of 90 degrees or greater (hereinafter, the state is also referred to as an opened state). As described later in more detail, the first support part 30 has an angle holding mechanism that holds the first fixing part 10 at an arbitrary angle within a predetermined range.

Similarly to the first fixing part 10, the second fixing part 20 is a member that has a substantially L-shaped section and a constant length in a width direction. The second fixing part 20 has a base end portion 21 and a holding portion 22 that is substantially orthogonal to the base end portion 21, when seen in a section. The second fixing part 20 is rotatably supported at a side lower than the first fixing part 10 by the second support part 40. The detailed configuration is explained next. The second fixing part 40 is provided to both sides of a lower end of the recessed part 91 formed on the backside of the seatback 90. The second fixing part 40 connects both sides of the lower end of the recessed part 91 and the base end portion 21 of the second fixing part 20 and supports the second fixing part 20 so that the second fixing part can be rotated in a downward direction. Specifically, the second support part 40 supports the second fixing part so that the second fixing part can be rotated from a state where the backside of the seatback 90 and the holding portion 22 of the second fixing part 20 are substantially parallel (hereinafter, the state is also referred to as a closed state) to a state where an angle between the backside of the seatback 90 and the holding portion 22 of the second fixing part 20 becomes about 90 degrees (hereinafter, the state is also referred to as an opened state).

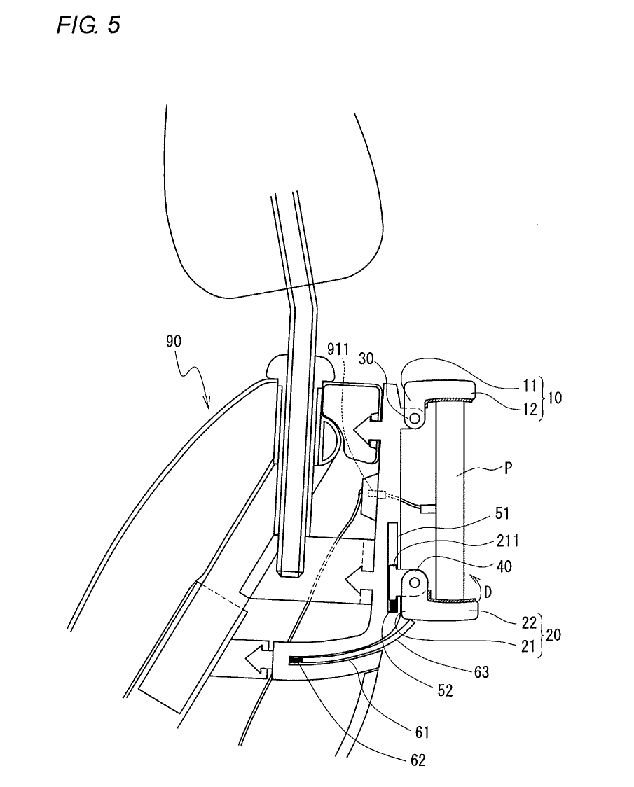

The second fixing part 20 is mounted to be slidable in a direction of getting close to and away from the first fixing part 10, together with the second support part 40. In other words, the second fixing part 20 is mounted to be slidable in the vertical direction. A slide mechanism of the second fixing part 20 is explained next. As shown in FIG. 4, a slide groove 51 having a predetermined length in the vertical direction is formed on an inner bottom surface of the recessed part 91 formed on the backside of the seatback 90. A base part of the based end portion 21 of the second fixing part 20 is engaged in the slide groove 51. The base part of the base end portion 21 has an engaging part 211 extending in the vertical direction. Since the engaging part 211 is engaged in the slide groove 51, the second fixing part 20 is not separated from the slide groove 51 even when the second fixing part 20 is pulled out in a rearward direction. Furthermore, a coil spring 52 for slide is provided in a lower side of the slide groove 51 below the base end portion 21 of the second fixing part 20. When the second fixing part 20 is moved in the downward direction, the spring 52 is compressed to press the second fixing part 20 in the upward direction (in the direction of getting close to the first fixing part 10) (refer to FIG. 5).

By the first fixing part 10 and the second fixing part 20 having the above configuration, the portable device P is fixed to the vehicle seat as explained next. First, the first fixing part 10 is rotated in the upward direction and the second fixing part 20 is rotated in the downward direction. In other words, the first fixing part 10 and the second fixing part 20 are rotated in the direction of getting away from each other. Then, the second fixing part 20 is slid in the downward direction against the pressing force of the spring 52. The second fixing part 20 is slid until an interval between the first fixing part 10 and the second fixing part 20 in the vertical direction becomes larger than the portable device P to be fixed, and then the portable device P is inserted between the first fixing part 10 and the second fixing part 20. At this state, by releasing the pressing force of the spring 52 engaged to the second fixing part 20, the second fixing part 20 is naturally slid in the upward direction to a size of the portable device P in the vertical direction. Thereby, the portable device P is sandwiched and fixed between the first fixing part 10 and the second fixing part 20 (the portable device is held by the pressing force of the spring 52). That is, the one fixing part is pressed toward the other fixing part, so that the interval between both fixing parts is naturally (without any operation) adjusted to the size of the portable device P.

In the meantime, a terminal 911 that is used to supply power to the portable device P is provided in the recessed part 91. In the drawings in which the terminal 911 is shown, only one terminal 911 is shown so as to easily understand the drawings. However, a variety of terminals 911 are preferably provided in the recessed part 91 so that variety of types of the portable device P can be used.

Next, an angle adjusting function of the fixing apparatus 1 according to the illustrative embodiment is described. The angle adjusting function is to adjust an angle of the portable device P for a case where an angle of the fixing apparatus 1 is changed depending on an inclined angle (reclining state) of the vehicle seat.

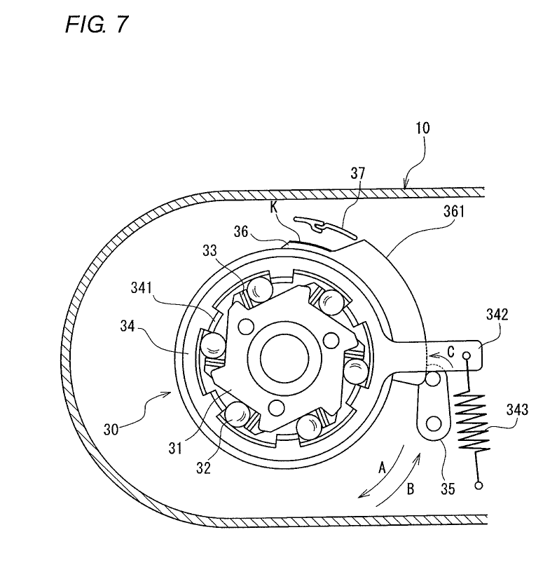

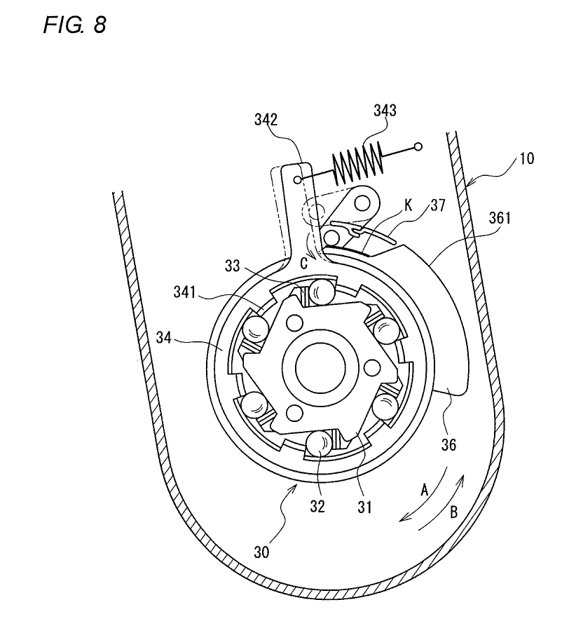

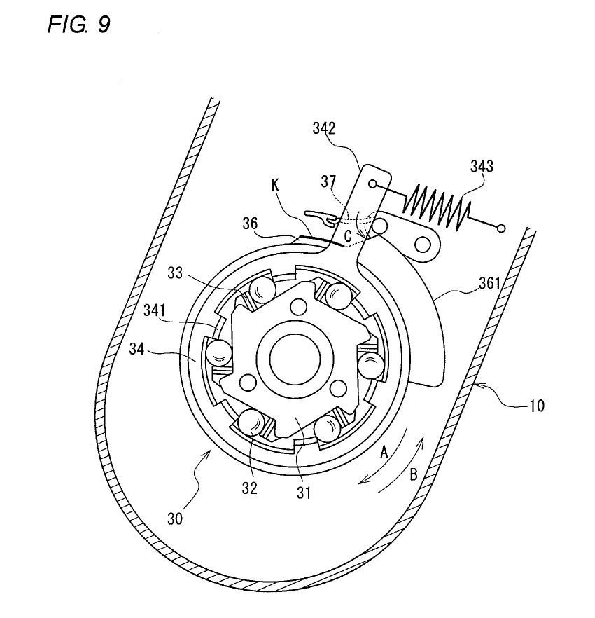

The first fixing part 10 can be held at an arbitrary angle within a predetermined range by the angle holding mechanism of the first support part 30. An example of the angle holding mechanism is described with reference to FIGS. 7 to 9. The angle holding mechanism has a cam member 31, a ball 32, a spring plate 33, a holding release member 34, a tilt member 35, a guide plate 36 and a plate spring 37.

The cam member 31 is a member having a waveform-shaped periphery and is rotated as the first fixing part 10 is rotated. The cam member 31 is provided at its periphery with a ring member (not shown), which forms a space together with the cam member 31 having a waveform-shaped periphery. The space is wider toward one side of the rotating direction (toward a direction of rotating the first fixing part 10 to the opened state; arrow B direction) and is narrower toward the other side (toward a direction of rotating the first fixing part 10 to the closed state; arrow A direction). The ball 32 is received in the space. The spring plate 33 presses the ball 32 toward the narrower direction of the space (arrow A direction). The holding release member 34 has a protrusion 341 that enters the space and is pressed in the arrow A direction by a tension spring 343. When the holding release member 34 is rotated in the arrow B direction against the pressing force of the tension spring 343, the protrusion 341 having entered the space presses the ball 32 in the wider direction of the space (arrow B direction). The tilt member 35 is pressed to rotate in an arrow C direction by a torsion coil spring (not shown). When the tilt member 35 is rotated in an opposite direction to the arrow C direction against the pressing force of the torsion coil spring, it acts on an arm 342 of the holding release member 34, thereby rotating the holding release member 34 in the arrow B direction. The guide plate 36 has a guide part 361 that protrudes toward an outer side in a radial direction. Even when the first fixing part 10 is rotated, the guide plate 36 is not rotated (the rotating direction position of the guide part 361 is not changed). When the tile member 35 is on the outer side of the guide part 361 of the guide plate 36, the tilt member 35 acts on the arm 342 of the holding release member 34. The plate spring 37 is mounted at a position extending in the arrow B direction along the periphery edge of the guide part 361 of the guide plate 36. The plate spring 37 has elastic force that is not changed even when the tilt member 35 pressed by the torsion coil spring acts on an outer surface of the plate spring.

The movement of the angle holding mechanism having the above configuration is described together with the rotation of the first fixing part 10. When it is intended to rotate the first fixing part 10 at the closed state to the opened state, the tilt member 35 is on the outer side of the guide part 361 of the guide plate 36. Accordingly, the tilt member 35 acts on the arm 34 of the holding release member 34, thereby rotating the holding release member 34 in the arrow B direction. As a result, the ball 32 is pressed in the wider direction (arrow B direction) of the space by the protrusion 341 of the holding release member 34. That is, when the ball 32 is positioned at the wider portion, the cam member 31 is not locked by the ball 32. Accordingly, the first fixing part 10 is easily rotated.

When the first fixing part 10 is gradually rotated in the direction toward the opened state, the tilt member 35 is moved while being on the outer side of the guide part 361 of the guide plate 36 and the outer side of the plate spring 37. When the first fixing part 10 becomes at the opened state, the state where the tilt member 35 is on the outer side of the plate spring 37 is released, and the tilt member 35 is thus moved in the inner side in the radial direction by the pressing force of the torsion coil spring. Then, the state where the tilt member 35 acts on the arm 342 of the holding release member 34 is released, and the holding release member 34 is rotated in the arrow A direction by the tension spring 343. Therefore, since the pressing state of the protrusion 341 of the holding release member 34 to the ball 34 is released, the ball 32 is pressed in the narrower direction (arrow A direction) by the spring plate 33. Thereby, when the ball 32 is moved in the narrower direction of the space and is sandwiched between the cam member 31 and the ring member located on the periphery of the cam member, the cam member 31 is blocked from being rotated in the arrow B direction. In other words, the first fixing part 10 is restrained from being rotated in the arrow B direction (the first fixing part 10 is braked). That is, in this illustrative embodiment, it is possible to hold the first fixing part 10 from the opened state to an arbitrary position (arbitrary angle) within a range within which the tilt member 35 is located at the inner side (the part shown with a reference numeral K in FIGS. 7 to 9; an angle of the part is referred to as θ degree) of the plate spring 37.

When the first fixing part 10 is further rotated in the A direction, the tilt member 35 pushes up the plate spring 37 in the outer side in the radial direction and again is positioned on the outer side of the guide part 361 of the guide plate 36. Thereby, the state where the first fixing part 10 is restrained from being rotated in the arrow B direction (the state where the first fixing part 10 is braked) is released.

As described above, in this illustrative embodiment, it is possible to hold the first fixing part 10 at an arbitrary angle within the angle θ (θ=α+β) from the state where the angle between the backside of the vehicle seat and the holding portion 12 of the first fixing part 10 is [90+α] degrees (from the opened state) to the state where the angle is [90−β] degrees by the angle holding mechanism. In other words, the angle holding mechanism is a brake mechanism of a stepless adjusting type that can adjust the angle of the first fixing part 10 within the angel θ in a stepless manner.

In the meantime, the above configuration of the angle holding mechanism is exemplary. In other words, the other configuration may be adopted inasmuch as it can hold the first fixing part 10 at a predetermined angle. For example, a ratchet mechanism may be used to stepwise adjust the angle of the first fixing part 10.

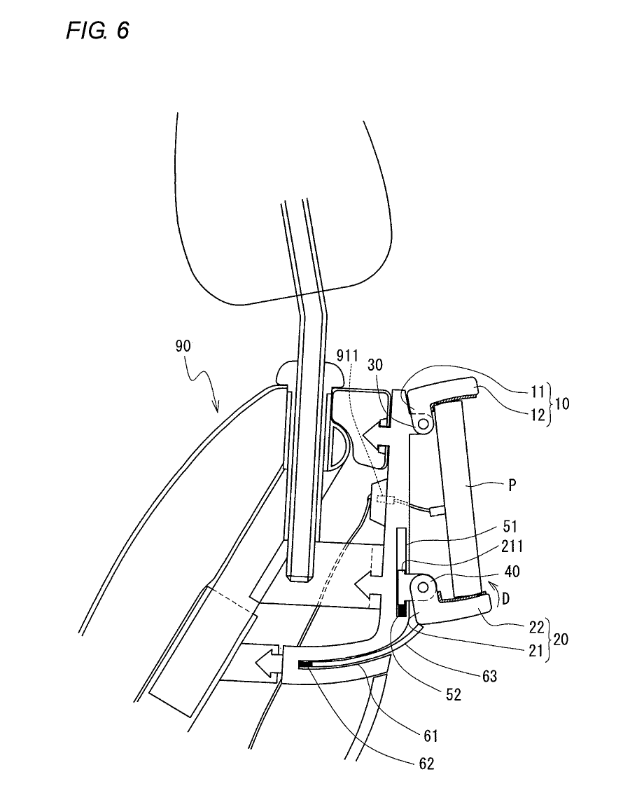

In the meantime, the second fixing part 20 is pressed in the rotating direction of getting close to the first fixing part 10 (direction of rotating the second fixing part to the closed state; arrow D direction shown in FIG. 5 or 6) by the rotation pressing mechanism. The rotation pressing mechanism shown in FIGS. 4 to 6 has a coil spring 62 for rotation and a pressing member 63 that is contacted to the second fixing part 20.

A pressing member accommodating part 61 that is elongated in the width direction and is a hole curved toward the second fixing part 20 when seen in a section is formed at a lower side of the recessed part 91, and the spring 62 and the pressing member 63 are accommodated in the pressing member accommodating part 61. The pressing member 63 is a plate-shaped member that is elongated in the width direction and is curved at the substantially same curvature as the pressing member accommodating part 61 when seen from a section. The pressing member 63 is pressed in the rearward direction (in a direction of protruding from the backside of the seatback 90) along the curved shape of the pressing member accommodating part 61 by the spring 63 for rotation. In the meantime, since the pressing member 63 is formed with a separation preventing part (not shown), the pressing member 63 is not completely separated from the pressing member accommodating part 61. A tip end of the pressing member 63 is contacted to the outer surface of the second fixing part 20. Accordingly, the second fixing part 20, which is rotatably supported by the second support part 40, is pressed by the pressing member 63 so that it is rotated in the rotating direction of getting close to the first fixing part 10 (direction of rotating the second fixing part to the closed state; arrow D direction).

The fixing apparatus 1 has the angle holding mechanism that holds the first fixing part 10 at a predetermined angle and the rotation pressing mechanism that presses the second fixing part 20 in the rotating direction of getting close to the first fixing part 10. By the angle holding mechanism and the rotation pressing mechanism, it is possible to realize the angle adjusting function of adjusting the angle of the portable device P to be fixed. In other words, when the angle of the first fixing part 10 is changed by the angle holding mechanism and the portable device P is sandwiched therebetween to follow the angle, the second fixing part 20, which is pressed in the rotating direction of getting close to the first fixing part 10, is rotated to the size or angle of the portable device P until it is brought into contact with the lower end of the portable device P. For example, when the portable device P has a rectangular parallelepiped shape, as shown, the first fixing part 10 is rotated until the holding portion 12 thereof is substantially parallel with the holding part 22 of the second fixing part 20. As can be seen from a comparison of FIGS. 5 and 6, the larger the angle between the backside of the vehicle seat and the holding portion 12 of the first fixing part 10, the upper end of the portable device P is tilted in a front direction, and the smaller the angle between the backside of the vehicle seat and the holding portion 12 of the first fixing part 10, the upper end of the portable device P is tilted in a rear direction. Accordingly, in this illustrative embodiment, regardless of the inclined angle (reclining state), it is possible to adjust the mount angle of the portable device P so that the portable device P can be easily used.

The fixing apparatus 1 according to the above illustrative embodiment realizes the following operational effects. First, in the fixing apparatus 1, the second fixing part 20 that is rotatably attached to the vehicle seat by the second support part 40 is sildably mounted in the directions of getting close to and away from the first fixing part 10 and is pressed in the direction of getting close to the first fixing part 10 by the spring 52. Accordingly, since the second fixing part 20 is slid depending on the size of the portable device P (the interval between the first fixing part 10 and the second fixing part 20 is determined depending on the size of the portable device P) and the portable device P is sandwiched and fixed between the first fixing part 10 and the second fixing part 20, it is possible to stably fix the portable device P of the various types. In addition, since the portable device is fixed just by sandwiching the portable device P between the first fixing part 10 and the second fixing part 20, the usability is high.

In addition, in the fixing apparatus 1 according to the above illustrative embodiment, the portable device P is sandwiched and fixed in the vertical direction between the first fixing part 10 and the second fixing part 20, so that it is supported in the gravity direction. That is, the portable device P is fixed more stably.

Also, according to the fixing apparatus 1 of the above illustrative embodiment, it is possible to change the angle of the portable device P by adjusting the angle of the first fixing part 10 by the angle holding mechanism. In other words, when the angle of the first fixing part 10 is adjusted depending on the inclined angle of the vehicle seat, the second fixing part 20 is also naturally rotated to the position at which it is contacted to the lower end of the portable device P, because the second fixing part 20 is pressed in the rotating direction of getting close to the first fixing part 10 by the rotation pressing mechanism. Therefore, it is possible to easily adjust the portable device P to the angle at which the portable device P can be easily used, depending on the inclined angle of the vehicle seat.

While the present invention has been shown and described with reference to certain illustrative embodiments thereof, it will be understood by those skilled in the art that various changes in form and details may be made therein without departing from the spirit and scope of the invention as defined by the appended claims. For example, following modified embodiments may be also useful.

In the above illustrative embodiment, the portable device P is sandwiched and fixed in the vertical direction between the first fixing part 10 and the second fixing part 20. However, the first fixing part 10 and the second fixing part 20 may be provided to oppose to each other in the width direction and the portable device P may be sandwiched and fixed in the width direction (horizontal direction).

In the above illustrative embodiment, the second fixing part 20 is pressed in the (upper) direction of getting close to the first fixing part 10 by the spring 52. However, the first fixing part 10 may be pressed in the (lower) direction of getting close to the second fixing part 20. In addition, both the first fixing part 10 and the second fixing part 20 may be pressed in the direction of getting close to the fixing parts of the other parts. According to this configuration, since the force of sandwiching the portable device P between the first fixing part 10 and the second fixing part 20 is increased, it is possible to fix the portable device P more stably.

In the above illustrative embodiment, the second fixing part 20 is pressed in the direction of getting close to the first fixing part 10 by the spring 52 and the portable device P is inserted between the two fixing parts. At that state, when the pressing force of the spring 52 for slide engaged to the second fixing part 20 is released, the second fixing part 20 is slid in the direction of getting close to the first fixing part 10 to the size of the portable device P. In other words, the interval between the first fixing part 10 and the second fixing part 20 is automatically set by the second fixing part 20 that is being pressed. However, the other configurations other than the configuration of using the pressing force may be adopted. For example, the configuration may be possible where at least one of the first fixing part 10 and the second fixing part 20 is provided to slide in the direction of getting close to and away from the other fixing part and the fixing part slidably provided is locked at a predetermined position. That is, the configuration may be appropriately changed inasmuch as the interval between first fixing part 10 and the second fixing part 20 can be set to the size of the portable device P.

In the above illustrative embodiment, the first fixing part is held at an arbitrary angle by the angle holding mechanism and the second fixing part is pressed in the direction of getting close to the first fixing part by the rotation holding mechanism. However, the angle holding mechanism may be configured to act on the second fixing part and the rotation holding mechanism may be configured to act on the first fixing part.

In the above illustrative embodiment, the fixing apparatus 1 is mounted on the seatback 90 of the vehicle seat. However, the fixing apparatus may be provided to the headrest of the vehicle seat.

What is claimed is:

1. A fixing apparatus for a portable device mounted to a vehicle seat, the fixing apparatus comprising:
a first fixing part that is supported rotatably by a first support part attached to the vehicle seat; and
a second fixing part that is supported rotatably by a second support part attached to the vehicle seat,
wherein at least one of the first and second fixing parts is configured to be slidable in a direction of getting close to and away from the other of the fixing parts, and
wherein the portable device is sandwiched and fixed between the first and second fixing parts.

2. The fixing apparatus according to claim 1,
wherein the first fixing part is supported rotatably in an upward direction by the first support part, and the second fixing part is supported rotatably in a downward direction by the second support part, and
wherein the portable device is sandwiched and fixed in a vertical direction between the first and second fixing parts.

3. The fixing apparatus according to claim 1, further comprising:
an angle holding mechanism configured to hold one of the first and second fixing parts at a predetermined angle; and
a rotation pressing mechanism configured to press the other of the fixing parts in a rotating direction of getting close to the one of the fixing parts.

4. The fixing apparatus according to claim 3,
wherein the other of the fixing parts which is pressed by the rotation pressing mechanism is configured to be slidable.

5. The fixing apparatus according to claim 3,
wherein the rotation pressing mechanism includes:
a pressing member accommodating part that is a hole curved toward the other of the fixing parts;
a spring that is accommodated in the pressing member accommodating part; and
a pressing member that has a plate shape and is curved at a substantially same curvature as the pressing member accommodating part, and
wherein the spring presses the pressing member along a curved shape of the pressing member accommodating part, so that the pressing member presses the other of the fixing parts.

6. The fixing apparatus according to claim 1, further comprising:
a spring which presses the at least one of the first and second fixing parts toward the direction of getting close to the other of the fixing parts.

7. The fixing apparatus according to claim 1,
wherein the first fixing part includes a first base end portion and a first holding portion that is substantially orthogonal to the first base end portion, so as to form an L-shape, and the first base end portion is rotatably supported by the first support part,
wherein the second fixing part includes a second base end portion and a second holding portion that is substantially orthogonal to the second base end portion, so as to form an L-shape, and the second base end portion is rotatably supported by the second support part, and
wherein the portable device is sandwiched and fixed between the first and second holding portions.
